(19) United States
(12) Patent Application Publication
(10) Pub. No.: US 2009/0056789 A1
(43) Pub. Date: Mar. 5, 2009

(54) Solar concentrator and solar concentrator array

(76) Inventor: Vladimir Draganov, Coquitlam (CA)

Correspondence Address: VLADIMIR DRAGANOV, 2807 RAMBLER WAY, COQUITLAM, BC, V3B 6S6, CA

(21) Appl. No.: 12/229,211

(22) Filed: Aug. 21, 2008

Related U.S. Application Data
(60) Provisional application No. 60/966,716, filed on Aug. 30, 2007.

(51) Int. Cl. H01L 31/052; H01L 31/18

(52) U.S. Cl. 136/246; 264/1.9

(57) ABSTRACT

A solar concentrator with a folded beam optical configuration allowing for compact, lightweight construction. Reflective optics may additionally be employed, including dichroic mirrors and/or antireflection coatings, to remove prevent unwanted infrared radiation reaching the solar cell. An array of such solar concentrators is also disclosed.

This application claims the priority of U.S. Provisional Application No. 60/966,716, filed Aug. 30, 2007, which is fully incorporated by reference as if fully set forth herein.

### BACKGROUND

The field of the present subject matter is the use of solar concentrators for the focusing of solar radiation onto photovoltaic cells for the generation of electricity.

Solar power generation is an effective and environmentally friendly energy option, and further advances related to this technology continue to increase the appeal of such power generation systems.

A solar concentrator array is described in U.S. Patent Application Publications Nos 2007/0089778 and 2006/0266408. Optical components of each unit include a front window, a primary mirror, secondary mirror and receiver assembly. Primary and secondary mirrors are defined by respective perimeters. The perimeters may be substantially coplanar and in contact with the front window. A base plate serves to radiate heat emitted by the solar cell, and in some embodiments an additional heat sink provides further passive cooling. A tapered optical rod within the receiver assembly directs received sunlight to the solar cell where electrical current is generated.

A solar concentrator with a solid optical element is described in U.S. Patent Application Publication No. 2006/0231133. It comprises Cassegrain-type concentrating solar collector cells with primary and secondary mirrors disposed on opposing convex and concave surfaces of a light-transparent optical element. Light enters an aperture surrounding the secondary mirror, and is reflected by the primary mirror toward the secondary mirror, which re-reflects the light onto a photovoltaic cell mounted on a central region. The primary and secondary mirrors are preferably formed as mirror films that are deposited or plated directly onto the optical element.

A solar concentrator disclosed in U.S. Pat. No. 6,276,359 has a primary parabolic and a secondary planar reflective surface. The use of dichroic mirrors in solar concentrators is disclosed in U.S. Pat. Nos. 4,328,389 and 7,081,584.

In the field of telescopes, U.S. Pat. No. 6,667,831 discloses a modified Gregorian design comprising three reflecting surfaces. The first reflecting surface is concave and is defined by an outer perimeter and an inner perimeter. The second reflecting surface is disposed between the first reflecting surface and the focal plane defined by the first reflecting surface. The third reflecting surface is concave and is disposed within the inner perimeter of the first reflecting surface. An aperture is disposed within the third reflecting surface for viewing the image. This type of telescope is useful when an upright, rather than inverted, image is required, and when the size of the telescope is critical. Also machining the first and third reflective surfaces using a turning cutting process renders this design not critical to the centering of two curved surfaces.

In accordance with further advancement in the field of solar generation technologies, it is desired to provide solar concentrator arrays with reflector configurations that are increasingly cost effective and overall simpler to manufacture. It is also desired that they are more compact, mechanically robust and lightweight for ease of tracking the sun.

### SUMMARY

Some embodiments of the presently disclosed technology provide for a solar concentrator that is axially compact, such that arrays of them are thin and lightweight. Reduced dimensions, lower cost as well as relative ease of assembly are some of the advantages afforded by select embodiments of the presently disclosed technology. One of the features of the disclosed technology contributing to these advantages is a flat secondary mirror. A related feature is that multiple secondary mirrors in an array can be made on a single flat piece of transparent material.

Ease of assembly of some embodiments of the present technology relates to the slackened assembly tolerances that are a result of the precise configuration of a combined, double curved primary and tertiary mirror. Both curved surfaces of the double curved primary and tertiary mirror may be made at the same time, obviating the need for alignment during assembly between two otherwise separate components. The relative position and tilt angle requirements of secondary mirrors in each concentrator assembly yields an arrangement in which received sunlight can be concentrated to given focal points with some degree of flexibility and potential misalignment.

Another advantage of the presently disclosed technology is the greater efficiency of rejection of infrared radiation. A feature of some of the embodiments of the technology disclosed is that solar radiation reflects off an infrared transmitting dichroic secondary mirror more than once, resulting in a higher rejection of infrared light and a correspondingly lower tendency to overheat one or more components, than if a single reflection occurred.

As is generally known by those skilled in the art, it is more difficult to test the optical quality of convex mirrors than it is for concave mirrors. Accordingly, the technology we disclose may be practiced without the need for convex mirrors.

A further advantage of solar concentrator arrays using the presently disclosed technology is that it is easy to track the position of the sun, due to a thin form and low weight resulting from the choice and arrangement of reflectors used.

Yet another advantage of the presently disclosed technology is that when dichroic mirrors are included, they can be coated on flat optics. As is generally known in this art, dichroic mirrors are easier to coat on and are of higher quality when on flat surfaces rather than curved surfaces.

Yet another advantage of the presently disclosed technology is that the optics may be achromatic, such that all wavelengths are focused substantially in the same spot. A further advantage is that the concentrator optics may be well corrected for coma and spherical aberration.

Yet another advantage of the presently disclosed technology is that it can be used with multi-junction solar cells. As is generally known in this art, multi-junction solar cells currently have a much higher efficiency compared to single junction solar cells. For example, triple-junction solar cells have three absorption layers, where each of the layers collects energy in the different region of spectrum. A further advantage is that each of the concentrators in the array can be used with a triple-junction cell where each cell is located at the prime focal point of the concentrator. Alternately, each concentrator can be used with two cells, for example one single junction, located in the intermediate focal point located after a flat secondary dichroic mirror and another, double-junction solar cell located at the primary focal point.

At least one of the preceding advantages is present in each of the various embodiments of the technology disclosed further in the Detailed Description.

Disclosed is a solar concentrator comprising a concave first reflecting surface for reflecting solar radiation towards a first focal plane defined by the first reflecting surface; a second reflecting surface optically coupled to the first reflecting surface and disposed between the first reflecting surface and the first focal plane, the second reflecting surface arranged to reflect the solar radiation towards a concave third reflective surface; the concave third reflecting surface optically coupled to the first reflecting surface by the second reflecting surface and configured to reflect the solar radiation to the second reflecting surface such that the solar radiation is reflected from the second reflecting surface towards a second focal plane defined by the combination of the first and third reflective surfaces; and a photovoltaic cell disposed in or near the second focal plane so as to intercept the solar radiation.

Also disclosed is an array of solar concentrators, wherein two or more of the second reflecting surfaces are disposed on a common substrate.

A method is also disclosed for manufacturing a solar concentrator array comprising the steps of molding or pressing a sheet of tessellating concave first reflecting surfaces, one or more first reflecting surfaces having an inner perimeter connected directly or via the sheet to a third reflecting surface; coating a plurality of second reflecting surfaces on a flat transparent cover; positioning a photovoltaic cell near or at the centre of each third reflecting surface; and assembling the sheet and the cover such that one or more second reflecting surfaces each align with a first reflecting surface, a third reflecting surface and a photovoltaic cell.

### BRIEF DESCRIPTION OF THE DRAWINGS

FIG. 1 shows a solar concentrator according to an embodiment of the present invention.

FIG. 2 shows a solar concentrator with two solar cells

FIG. 3 shows an array of solar concentrators

FIG. 4 shows a solid solar concentrator

FIG. 5 shows an array of solar concentrators in section

FIGS. 6-9 show alternate embodiments of a solar concentrator

### DETAILED DESCRIPTION

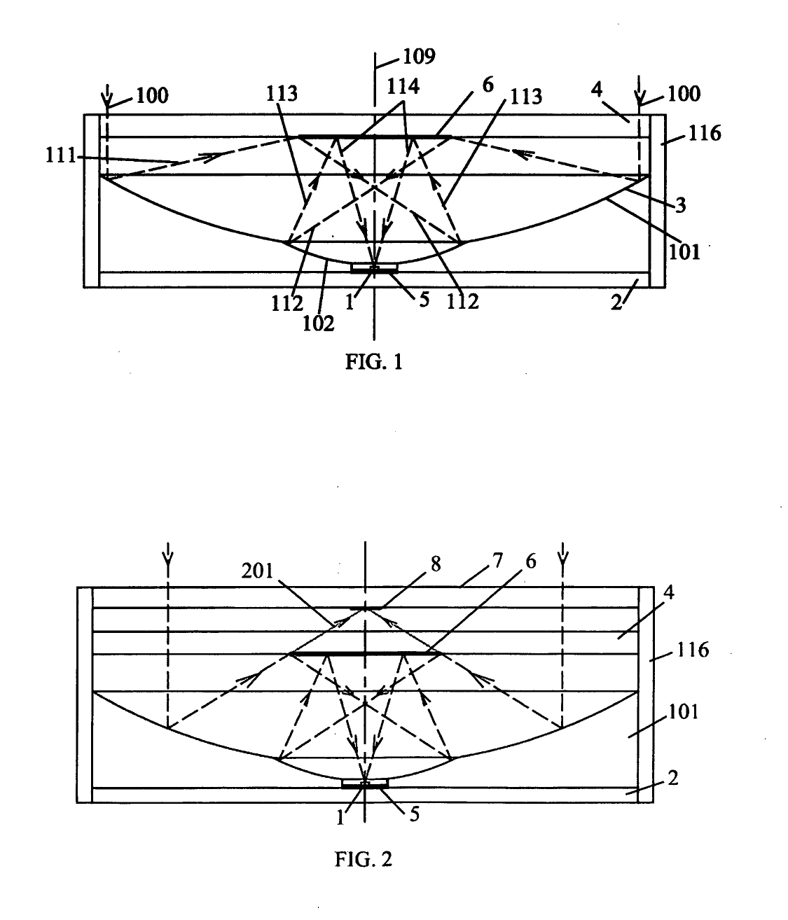

A solar concentrator module 100 with a folded beam configuration according to an embodiment of the present invention is shown in section in FIG. 1. The concentrator 100 comprises a unitary reflector 101, which comprises primary reflector 3 and a tertiary reflector 102. The unitary reflector 101 is mounted on a base plate 2, which may be made of a lightweight or low density rigid material such as aluminum, aluminum alloy or plastic, although other materials such as ceramics or steel may be used. The form of such base plate may comprise ridges or other features to improve rigidity. The base plate 2 may incorporate hollows or recesses to reduce its weight and material costs. The unitary reflector 101 may be solid, hollow or partially hollowed out. A second reflecting surface 6 is located on the surface of the planar, transparent cover or substrate 4, which may be made of glass or plastic. The tertiary reflecting surface 102 includes an aperture 103.

The reflecting surfaces 3, 6 and 102 may be formed or coated with aluminum, silver, gold or any other type of highly efficient reflective coating, and the reflecting surfaces may be polished.

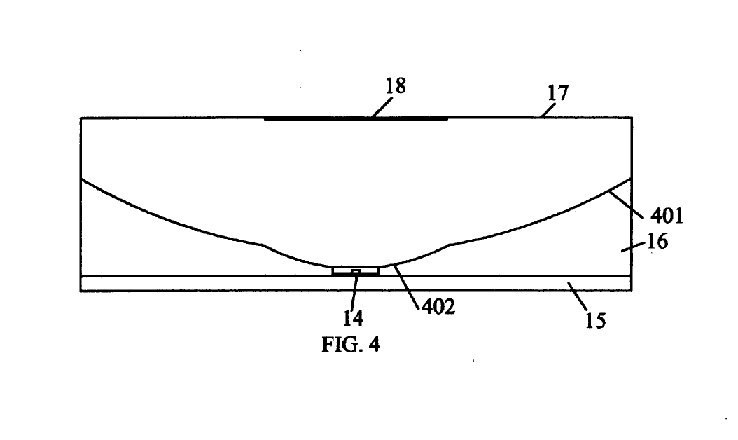

The shape of the cover 4, unitary reflector 101, reflector 6 and aperture 103 may be circular as viewed from above. Other shapes may instead be used for these elements, and may be more beneficial in the collection of solar radiation when an array of solar concentrators is assembled or manufactured. For example, as shown in FIG. 3, some or all of the above items may be made hexagonal or less preferably square in order to allow tessellation of the concentrators in an array 10. The shape of the primary mirror may be hexagonal and the secondary mirror may be circular as in concentrator 9. The shape of the primary mirror may be hexagonal and the secondary mirror may be hexagonal as in concentrator 11. The shape of the primary mirror may be hexagonal and the tertiary mirror 13 may be hexagonal as in concentrator 12. In a panel of such concentrators, the shapes of the concentrators at the edges of the array may be truncated so that they fit neatly within a rectangular, square or other shaped panel. In an array, each of the secondary mirrors 6 has a diameter of typically about a third of the outer diameter of the primary mirror 3, for minimum obscuration of the incoming sunlight while optimizing the amount of sunlight concentrated. Other diameters of the secondary mirror 6 may be permissible depending on possible variations of this embodiment.

Referring to FIG. 1, the primary 3 and tertiary 102 mirrors are both concave, with the curvature of the tertiary mirror 102 being greater than the curvature of the primary mirror 3. In FIG. 1, both the primary mirror 3 and the tertiary mirror 3 have elliptical curvatures (i.e., conic between −1 and 0). Those skilled in the art will recognize that with both mirrors having elliptical curvatures, correcting for both spherical and coma aberrations is facilitated without the need for additional optical elements. In an alternative embodiment, the primary mirror 3 may have a parabolic curvature (i.e., conic equal to −1) and the tertiary mirror 102 may have an elliptical curvature. Other curvatures may also be used for the primary and tertiary mirrors 3 and 102 of the solar concentrator.

The optical axes 109 of the primary and tertiary mirrors are coincidental. Additionally, the aperture 103 and the secondary reflector 6 are centered upon the coincident optical axes 109. Non-coincidental and/or off-axis optics may be employed, however, coincident optical axes reduce complications in aligning the optical elements and simplify the optics of the solar concentrator.

In the embodiment of FIG. 1, the primary and tertiary mirrors 3, 102 form the integral reflector 101. Such a double-curved reflector facilitates manufacturing and optical axis alignment of each reflector on the unitary reflector surface 101. This is important because smaller errors in axis alignment result in smaller optical aberrations. For example, a double-curved mirror may be manufactured using diamond turning or other appropriate equipment that is frequently used to create high quality mirrors. With the appropriate manufacturing equipment, the primary and tertiary mirrors may be manufactured sequentially using a single piece of equipment without realigning the equipment to obtain coincidental optical axes. For example, a blank piece of material such as aluminum is positioned and fastened in the chuck of a lathe. The reflector 3 is then formed by turning, then, leaving the partially worked blank fastened in the same way in the chuck, the reflector 102 is turned.

Alternatively, in lieu of a double curved mirror, the solar concentrator may comprise a primary reflector having an annular shape with a third reflecting surface as a separate component disposed within the inner radius of the first reflecting surface. The curvatures of this alternative embodiment for the first and third reflecting surfaces are the same as the curvatures for the primary 3 and tertiary 102 mirrors, respectively. In this variant, an alignment step between the primary mirror 3 and tertiary mirror 102 will be required.

Returning to FIG. 1, the second reflecting surface 6 is a planar surface. The reflector 6 optically couples the primary mirror 3 to the tertiary mirror 102. The reflector 6 is disposed between the primary mirror 3 and the focal plane of the primary mirror 3. Thus, light from a far field 110 may enter solar concentrator 100 and reflect off the primary mirror 3 towards the secondary mirror 6 along the path 111. The secondary mirror 6 reflects such light along path 112 towards the image of the focal plane of primary mirror and towards the tertiary mirror 102, which reflects the light back along path 113 towards the secondary mirror 6. Upon a second reflection from the secondary mirror 6, the light travels along path 114 and passes through the aperture 103 towards the focal plane of the concentrator. Light passing into aperture 103 is incident on photovoltaic cell 1, positioned at the focal plane of the concentrator. In the photovoltaic cell, radiant solar energy is converted to electrical energy.

The photovoltaic cell 1 may be mounted on a heatsink or heat spreader plate 5, which is in good thermal contact with the base plate 2. The base plates 2 may have heat sinking features, such as fins, or may be connected to an active or passive thermal dissipation system directly or by a heat pipe or thermal siphon.

The photovoltaic cell may be a highly efficient photovoltaic cell comprised of multiple layers, typically known as a multi-junction solar cell. Other photovoltaic cells may be used, such as dye-sensitized solar cells, photoelectrochemical cells, polymer solar cells, quantum dot solar cells, multi-spectrum solar cells, single layer or any other device for converting solar radiation into electrical energy. For minimizing cost, the area of the photovoltaic cell should be as small as possible while still capturing the maximum amount of solar radiation. Minimizing the area of the photovoltaic cell puts a very tight tolerance on the pointing accuracy of a concentrator or each of the concentrators in an array. In the configuration we disclose, the focal plane of the primary reflector 3 is located just beyond the secondary mirror 6. This makes the entire system compact, allows for easy alignment of primary and secondary mirrors, and permits smaller and therefore lower cost photovoltaic cells to be used.

On the top of the solar concentrator a piece of flat glass 4 or other transparent material may be spaced apart from the double curved reflector 101 with sidewalls 116. Locating features on the sidewalls 116, cover 4 or double reflector 101 may be present for assisting in optical alignment during assembly of the concentrator. The concentrator may be ventilated and may include pathways for egress of unwanted moisture. The concentrator may include desiccant in a location that does not obscure the light path, such as in recesses in the reflector 101 in the vicinity of the aperture 103. A piece of flat glass 4 or other transparent material may be sealed with sidewalls 116 to the double curved reflector 101 to create an environmentally sealed solar concentrator.

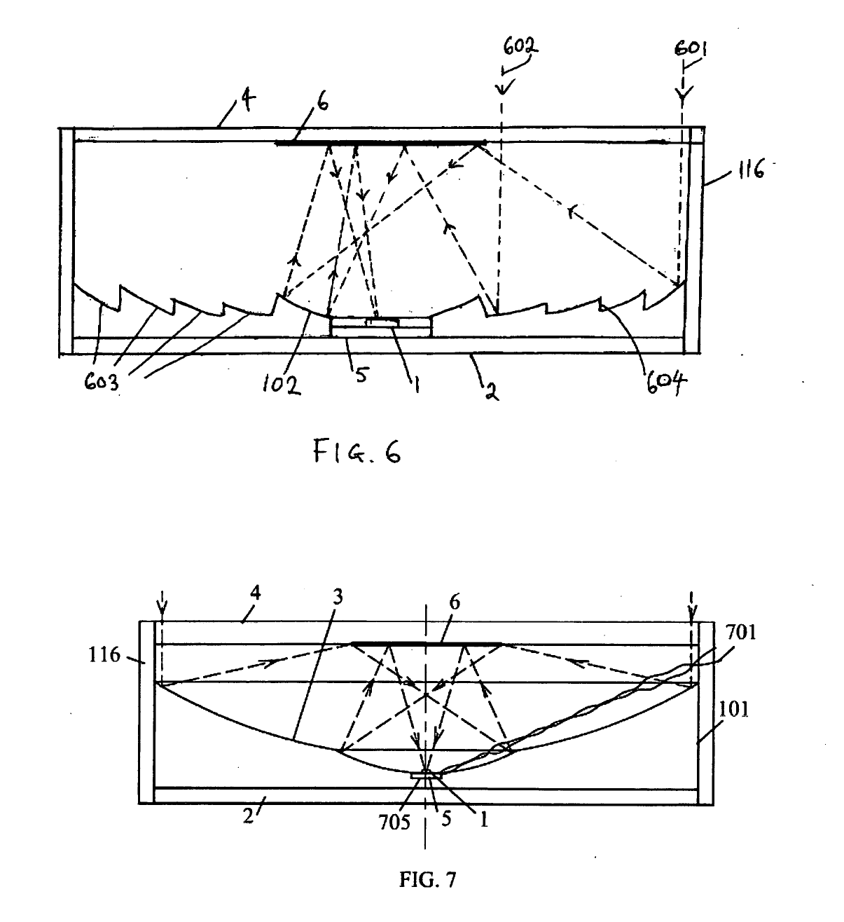

Referring to FIG. 5, which corresponds to a view along Section A-A in FIG. 3, an array of solar concentrators may have a common flat glass cover 501 to cover several concentrators mounted on a common base 502. A number of secondary reflectors 6 are located on the inner surface of the common flat glass cover 501, each secondary reflector 6 aligned with a corresponding primary reflector 504 and tertiary reflector 506. Sidewalls 503 accurately space the cover with its secondary reflectors 6 from the primary and tertiary mirrors 505. The sidewalls 503 may seal the array from the environment. A large array may comprise spacing posts or other mechanical spacing means in order to maintain an accurate spacing and optical alignment between the secondary mirrors 6 and the primary and tertiary mirrors 504 and 506. In an array of solar concentrators according to the technology disclosed herein, the primary and tertiary mirrors for all the concentrators may be made as one component, for example by moulding, pressing or other suitable means, or they may be made in units, each unit comprising a single primary and a single tertiary mirror. The secondary mirrors 6 in an array may all be located on a common flat piece of glass. Once the primary and tertiary mirrors are aligned with the cover carrying the secondary mirrors, no further alignment between the concentrators within the array is necessary. The form of base plate 502 may comprise ridges or other features to improve rigidity. The base plate 502 may incorporate hollows or recesses to reduce its weight and material costs

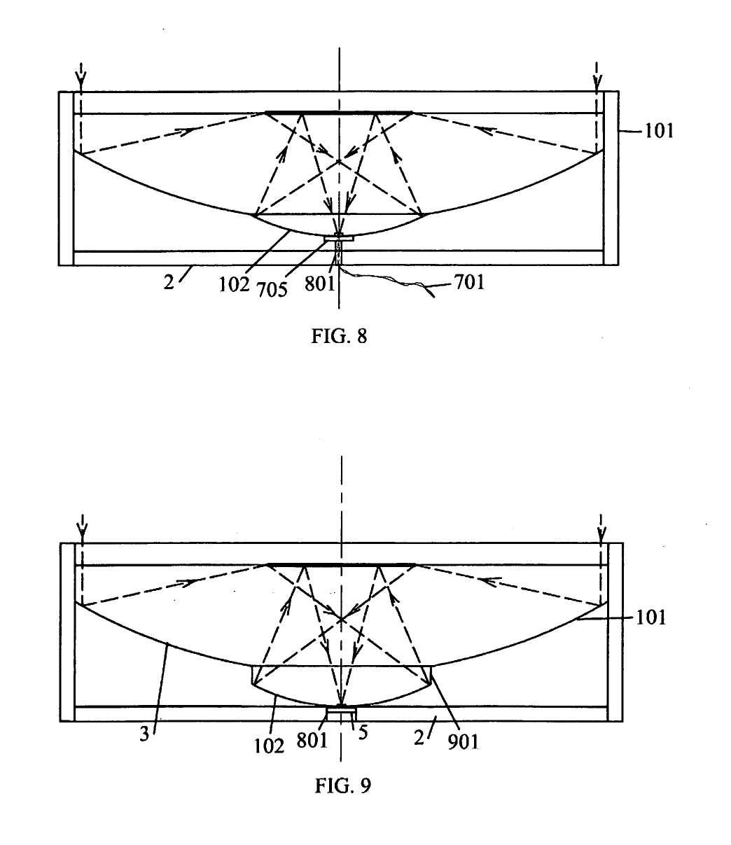

An alternate embodiment is shown in FIG. 6, in which the primary reflector has been segmented into four smaller reflecting regions 603, like a Fresnel type mirror. The primary reflector can be split into more or less than four regions. The smaller surfaces 604 connecting neighboring reflecting regions 603 can be vertical or sloped. The reflector segments 603 may be curved in section or flat. Example rays from the sun 601 and 602 are shown reflecting from the mirrors in the concentrator and being focused on the photovoltaic cell 1, mounted on heatsink 5. The primary reflector in this embodiment may be made thinner than other primary reflectors, and the concentrator may also be made thinner. The tertiary mirror 102 may also be segmented into two or more annular facets, in a similar fashion to that used for the primary mirror.

Alternative embodiments of the compact telescope may include a curved secondary mirror. A curved secondary mirror preferably has a large radius of curvature, such as a radius of 1 meter or more. Smaller radii of curvature may also be employed.

The flat secondary mirror 6 may be formed by coating the glass cover 4 with a dichroic coating. In this case part of the radiative spectrum of the sun may be reflected into the aperture 103 of the solar concentrator and another part of the spectrum may pass through the secondary mirror 6 to be focused outside the flat glass cover 4. This can have several benefits. For example, a photovoltaic cell 1 may be placed in or near to the focal point of the concentrator. Since not all solar energy can be converted into electrical energy in a photovoltaic cell, the unused part of this energy may produce heat which can overheat the detector. With secondary mirror 6 as a dichroic mirror, the infrared part of the spectrum may pass out of the concentrator and not focus on the photovoltaic cell. An advantage of the solar concentrator and solar concentrator array we disclose is that it is technically much easier to put a high quality, efficient dichroic mirror coating on a flat surface than it is on a curved surface. Dichroic mirrors may be formed by physical or chemical vapor deposition techniques, sputtering or other deposition techniques, using a masking process to prevent neighboring areas from being coated. An antireflection coating may be applied on one or both sides of the glass cover 4 in areas not coated with the mirror coating. The mirrors 6 may be formed as separate components then attached to the cover 4 using adhesive, a clip-fit or any other suitable process.

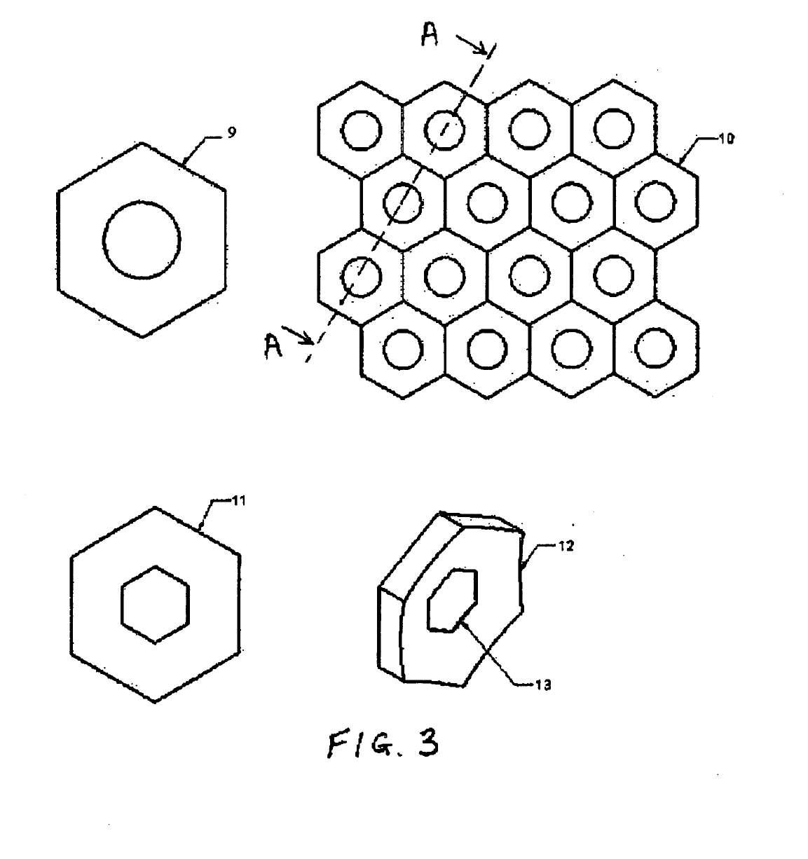

In an alternate embodiment of the technology disclosed herein, shown in FIG. 2, it is possible to put an infrared sensitive solar cell 8 on a transparent mounting plate 7 behind the dichroic secondary mirror 6. It is possible for the infrared part of the spectrum to pass out of the concentrator through dichroic mirror 6 along path 201, to detector 8. This infrared detector may produce additional electrical energy, which can increase the overall efficiency of the concentrator. In this case, for example, double-junction solar cell can be used at or near the prime focal point of the concentrator and single junction infrared solar cell 8 can be placed at or near preliminary focal point of the concentrator.

Usually, land based solar tracking systems can track the sun automatically based solely on the location of the solar concentrator panel and the time of the year. For some applications, for example space based panels, it may be important to track the sun using active tracking techniques. This may be done, for example, with a quad-cell photodetector located in the focal point of the tracking optics. Referring to FIG. 2, a quad-cell photodetector may be placed in the focal plane after the secondary flat mirror 6, for example at position 8. This will reduce cost of the system and will make it more compact.

The use of reflecting optics rather than refracting optics, such as lenses, generally facilitates the formation of an achromatic optical system. An alternate embodiment is possible if achromaticity is not a critical issue, in which a lens may be added to each concentrator. In a concentrator, or in each concentrator of an array, the area of the secondary flat mirror 6 is not used for capturing incident sunlight. Using this area as a footprint, a lens may be added to focus the previously uncaptured light onto an additional photovoltaic cell.

In another embodiment, an inexpensive photovoltaic cell may be placed on the outside of cover 4, in the area opposite to the secondary mirror 6, so that more of the incident sunlight is used to generate electrical energy. Electrically conducting traces on the surface or within the cover 4 may then be used to carry electrical energy away from the photovoltaic cell.

Additional non-imaging components such as compound parabolic concentrators or other alternative components can be added to one or both of the solar cells 8 and 1 to increase the field of view of the solar concentrator module.

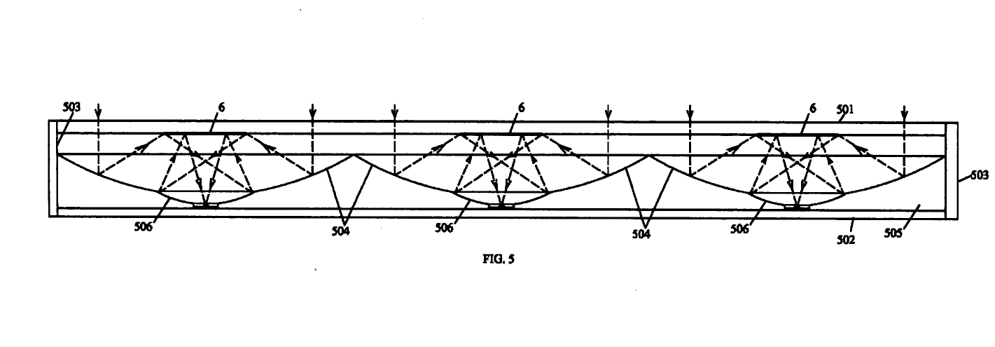

In an alternate embodiment, a solar receiver module can be made from the solid piece of glass or other optically transparent material. Referring to FIG. 4, a solid transparent component 17, made from glass for example, provides the support for primary reflector 401, secondary reflector 18 and tertiary reflector 402. The secondary reflector may be a dichroic coating, and the primary and tertiary mirrors 401 and 402 may be formed with coatings on item 17.

In a further alternate, the covers 4 and 501 may reflect or absorb infrared radiation, while transmitting radiation of higher wavelengths which are more useful for the generation of photovoltaic electricity.

In an alternate embodiment of the technology disclosed herein, the same principles may be used in solar concentrator architectures utilizing cylindrical optics configuration. For example, referring to FIG. 6, the reflector regions 603 may become planar mirror strips, or they may be shallow, tilted troughs. The cover 4 may be omitted except where secondary mirror 6 is coated or mounted, and cover 4 may be supported at the ends of a cylindrical optic style concentrator.

Yet a further embodiment is depicted in FIG. 7. In this embodiment, the heatsink 5 is mounted in a recess 705 in the unitary reflector 101. The heatsink 5 supports the photovoltaic cell 1. An advantage of this arrangement is that an aperture is not required in the tertiary reflector 102. The amount of material between the lower surface of the heatsink and the upper surface of the base plate 2 should be as little a possible to enhance thermal conduction from the photovoltaic cell, through the heatsink and base plate to the ambient air. In this embodiment, the wires 701 carrying the power from the photovoltaic cell are thin and can pass over the unitary reflector 101 without significantly affecting the overall solar radiation pattern within the concentrator.

It is not essential for the heatsink to be positioned in a recess 705, nor for it to lie flush with the upper surface of the tertiary reflector 102. Instead, the recess may be shallower, and the heatsink may sit slightly proud of the tertiary reflector surface. Instead of a recess, there may be a flat in the centre of the tertiary reflector, the heat sink being mounted on this flat. Alternately, the flat may be raised so that it stands proud of the tertiary reflecting surface. The heatsink may then be mounted on the platform thus created. The heatsink may have a recess in its lower surface into which the platform is located, for assistance with alignment.

FIG. 8 is similar to FIG. 7 and shows an alternate path for the electrical wires 701. In this embodiment, the heatsink 5 sits in a recess 705 in the tertiary mirror 102 of the unitary reflector 101. The wires 701 are passed through one or more feedthroughs 801 passing through the heatsink 5, the unitary reflector 101 and the supporting base 2. The feedthroughs may be axial or offset, and may be perpendicular or inclined in relation to the base plate 2. As for the embodiment in FIG. 7, the surface on which the heatsink is mounted may be below, flush or proud of the tertiary reflecting surface. For the position selected, the curvature of the mirrors and the position of the secondary mirror should be selected for focusing the solar radiation optimally onto the photovoltaic cell 1. In the embodiments in FIG. 7 and FIG. 8, the feedthroughs may be sealed or not sealed.

In the embodiment of FIG. 9, the primary 3 and tertiary 102 mirrors are shown vertically displaced from each other by a step 901. In this case, and if the unitary reflector 101 is hollow, thermal expansion and contraction of the unitary reflector 101 can occur more freely than if the primary and tertiary mirrors were connected at their respective inner and outer perimeters. This is due to the thermal expansion and contraction being taken up by the step, which can incline inwards and outwards accordingly. As a result, optical distortion of the reflecting surfaces is reduced. This becomes more important as arrays of such concentrators become larger. In this embodiment, the heatsink 5 is mounted in the base plate 2 which has feedthroughs 801 for the electrical wires carrying power from the photovoltaic cell 1. The step may be made of the same, thinner or thicker material then the reflecting surfaces, and may be further configured to provide a limited amount of rigidity for larger arrays.

Embodiments other than those shown or described are possible. For example, one or more features from one embodiment may be taken and combined with one or more features form another embodiment. It will be apparent to those skilled in the art that many more embodiments are possible without departing from the scope and concepts found herein.

I claim:

1. A solar concentrator comprising:
a concave first reflecting surface for reflecting solar radiation towards a first focal plane defined by the first reflecting surface;
a second reflecting surface optically coupled to the first reflecting surface and disposed between the first reflecting surface and the first focal plane, the second reflecting surface arranged to reflect the solar radiation towards a concave third reflective surface;
said concave third reflecting surface configured to reflect the solar radiation to the second reflecting surface in such a way that the solar radiation is then reflected from the second reflecting surface towards a second focal plain defined by the first concave reflecting surface, the second reflecting surface and the third concave reflecting surface;
a photovoltaic cell disposed in or near the second focal plane so as to intercept the solar radiation.

2. A solar concentrator according to claim 1 wherein the first focal plane and the second focal plane are substantially parallel.

3. A solar concentrator according to claim 1 wherein the first reflecting surface, the second reflecting surface and the third reflecting surface have a common axis.

4. A solar concentrator according to claim 1 wherein the curvature of the third reflecting surface is greater than the curvature of the first reflecting surface.

5. A solar concentrator according to claim 1 wherein the third reflecting surface is smaller than the first reflecting surface.

6. A solar concentrator according to claim 1 wherein the first reflecting surface and the third reflecting surface are unitary.

7. A solar concentrator according to claim 1 wherein the second reflecting surface is planar.

8. A solar concentrator according to claim 1, wherein the second reflecting surface reflects visible radiation and transmits infrared radiation.

9. A solar concentrator according to claim 8, comprising an infrared solar cell disposed in or near the first focal plane.

10. A solar concentrator according to claim 1, comprising a quad-cell photodetector disposed in or near the first focal plane.

11. A solar concentrator according to claim 1 comprising a cover having a lower side and an upper side, wherein said second reflecting surface is disposed on said lower side and a photovoltaic cell is disposed on said upper side opposite said second reflecting surface.

12. A solar concentrator according to claim 1, wherein the first reflecting surface is divided into constituent segments that are collectively disposed to have an overall lower profile than if the first reflecting surface were undivided.

13. An array of solar concentrators, each concentrator according to claim 6, wherein two or more second reflecting surfaces are disposed on a common substrate.

14. An array of solar concentrators according to claim 13, wherein two or more first reflecting surfaces and two or more third reflecting surfaces are unitary.

15. An array of solar concentrators according to claim 14, wherein one or more first reflecting surfaces have a hexagonal outer perimeter and said array is a hexagonal array.

16. An array of solar concentrators according to claim 14, wherein one or more first reflecting surfaces have a square outer perimeter and said array is a square array.

17. An array of solar concentrators according to claim 13 comprising a moisture management system.

18. A method of manufacturing a solar concentrator array comprising the steps of:
molding or pressing a sheet of tessellating concave first reflecting surfaces, one or more first reflecting surfaces having an inner perimeter connected directly or via the sheet to a third reflecting surface;
coating a plurality of second reflecting surfaces on a flat transparent cover;
positioning a photovoltaic cell near or at the centre of each third reflecting surface;
assembling the sheet and the cover such that one or more second reflecting surfaces each align with a first reflecting surface, a third reflecting surface and a photovoltaic cell.
